(19) United States
(12) Patent Application Publication
(10) Pub. No.: US 2024/0425352 A1
(43) Pub. Date: Dec. 26, 2024

(54) INERTIAL MEMS DEVICE INTEGRATING A WAKE-UP ELEMENT, INERTIAL MEMS SYSTEM AND MANUFACTURING METHOD

(71) Applicant: STMicroelectronics International N.V., Geneva (CH)

(72) Inventors: Luca SEGHIZZI, Milano (IT); Federico VERCESI, Milano (IT); Gianluca LONGONI, Cernusco sul Naviglio (IT); Andrea NOMELLINI, Milan (IT)

(73) Assignee: STMicroelectronics International N.V., Geneva (CH)

(21) Appl. No.: 18/741,058

(22) Filed: Jun. 12, 2024

(30) Foreign Application Priority Data
Jun. 23, 2023 (IT) 102023000013002

(51) Int. Cl. B81B 3/00; G01P 15/125

(52) U.S. Cl. CPC B81B 3/0021; G01P 15/125; B81B 2201/0235; B81B 2201/0242; B81B 2203/0118; B81B 2203/0127; B81B 2203/04

(57) ABSTRACT

An inertial MEMS device includes an inertial element provided by a movable structure that is responsive to movement. The moveable structure is formed in a first structural layer of semiconductor material. A suspended structure extends above the movable structure at a distance therefrom. The suspended structure is formed in a second structural layer of semiconductor material and carries a piezoelectric structure. The suspended structure and the piezoelectric structure form a wake-up element that generates an activation signal in presence of vibrations or shocks. The inertial element and the wake-up element are contained in a chamber formed by a substrate and a cap, together with peripheral portions of the first and the second structural layers.

### PRIORITY CLAIM

This application claims the priority benefit of Italian Application for Patent No. 102023000013002, filed on Jun. 23, 2023, the content of which is hereby incorporated by reference in its entirety to the maximum extent allowable by law.

### TECHNICAL FIELD

The present invention relates to an inertial micro-electro-mechanical system (MEMS) device integrating a wake-up element, an inertial MEMS system and a manufacturing method. In particular, the considered inertial MEMS device comprises one or more inertial sensors, such as an accelerometer and/or a gyroscope, formed in at least one silicon structural layer and defining at least one movable structure. The movable structure generally has a main extension in an extension plane and is movable in-plane or out-of-plane.

### BACKGROUND

As known, inertial micro-electro-mechanical system (MEMS) devices are increasingly being used in consumer, automotive and industrial applications, often integrating two or more inertial sensors in a same die and which are packaged together with the related control circuits, generally formed in a separate die and forming an Application Specific Integrated Circuit (ASIC), hereinafter also referred to as control circuit.

In many applications, it is often desired that the inertial MEMS device is always on active as to be capable of real-time sensing of movements and/or variations in the surrounding environment.

To this end, generally, the control circuits are always on. When the system is at rest, the control circuit keeps the inertial MEMS device on in a low-consumption condition (low working frequency) so that it may sense environmental changes and generate interrupt signals; upon receiving the interrupt signals, the control circuit activates the normal (high-frequency and high-consumption) operation of the system.

As a result, even in rest conditions of the system, the inertial MEMS device is kept active (or “awake”), even if at low frequency, and has a non-negligible consumption. However, this is unwanted since it prevents or at least limits the use of such systems in applications and conditions in which low consumption and/or long duration is required, without having an external power source.

To overcome this issue, it has already been proposed to provide an activation or “wake-up” structure arranged alongside the inertial MEMS device, integrated in the same die or in a suitable adjacent die. In rest condition, the inertial MEMS device is off and does not consume. When an environmental change occurs, the activation structure senses it and sends a signal to the control circuit which activates the inertial MEMS device.

However, this arrangement increases the size of the overall device. Furthermore, sometimes, the total energy consumption is still too high compared to what desired in some applications.

There is a need in the art to provide a solution which overcomes the drawbacks of the prior art.

### SUMMARY

Embodiments herein concern an inertial MEMS device, an inertial MEMS system and a manufacturing process.

In an embodiment, an inertial MEMS device comprises: an inertial element responsive to movement, including a movable structure formed in a first structural layer of semiconductor material; a suspended structure extending above the movable structure, at a distance therefrom, the suspended structure being formed in a second structural layer of semiconductor material; and a piezoelectric structure arranged on the suspended structure, the suspended structure and the piezoelectric structure forming a wake-up element configured to generate an activation signal in presence of vibrations or shocks.

In an embodiment, an inertial MEMS system comprises: the inertial MEMS device as previously described, and a control circuit. The control circuit is electrically coupled to the inertial MEMS device and is configured to: receive the activation signal; compare the activation signal with a first threshold and a second threshold, greater than the first threshold; activate the inertial MEMS device with low-consumption operation if the activation signal is greater than the first threshold and smaller than the second threshold; and activate the inertial MEMS device with high-consumption operation if the activation signal is greater than the second threshold.

In an embodiment, a method for activating an inertial MEMS device comprises: receiving an activation signal; comparing the activation signal with a first threshold and a second threshold, greater than the first threshold; activating the inertial MEMS device with low-consumption operation if the activation signal is greater than the first threshold and smaller than the second threshold; and activating the inertial MEMS device with high-consumption operation if the activation signal is greater than the second threshold.

In an embodiment, a process for manufacturing an inertial MEMS device comprises: forming a first structural layer of semiconductor material on a substrate; forming an inertial element, including a movable structure, in the first structural layer; forming a second structural layer of semiconductor material on the first structural layer; forming a suspended structure in the second structural layer, the suspended structure extending above the movable structure, at a distance therefrom; and forming a piezoelectric structure above the suspended structure, wherein the suspended structure and the piezoelectric structure form a wake-up element configured to generate an activation signal in presence of vibrations or shocks.

### BRIEF DESCRIPTION OF THE DRAWINGS

For a better understanding of the present invention, some embodiments thereof are now described, purely by way of non-limiting example, with reference to the attached drawings, wherein:

FIG. 1 shows a block diagram of an inertial MEMS system including an inertial MEMS device;

FIG. 2 is a schematic top-view of an embodiment of the inertial MEMS system;

FIG. 3 is a flow diagram relating to a possible work mode of the inertial MEMS system;

FIGS. 4A and 4B are cross-sections, taken along section lines A-A and B-B, respectively, of FIG. 5, of an embodiment of the inertial MEMS device;

FIG. 5 is a top-plan view of a possible layout of the inertial MEMS device of FIGS. 4A and 4B;

FIG. 6 is a top-plan view of a different possible layout of the inertial MEMS device of FIGS. 4A and 4B;

FIGS. 7A-15A are cross-sections, similar to FIG. 4A, through a semiconductor wafer in successive manufacturing steps of the inertial MEMS device of FIG. 5; and

FIGS. 7B-15B are cross-sections, similar to FIG. 4B, through the semiconductor wafer of FIGS. 7A-15A, in successive manufacturing steps of the inertial MEMS device of FIG. 5, wherein FIGS. 7A-15A and 7B-15B having the same figure number (7-15) relate to a same manufacturing step.

### DETAILED DESCRIPTION

The following description refers to the arrangement shown; consequently, expressions such as “above”, “below”, “upper”, “lower”, “right”, “left” relate to the accompanying figures and should not be interpreted in a limiting manner.

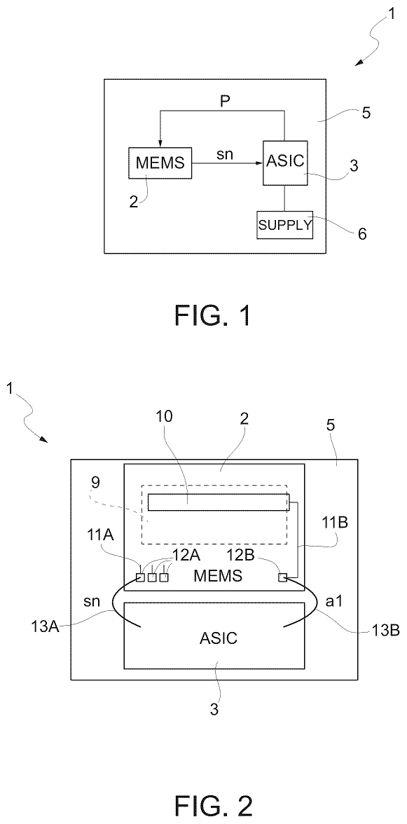

FIG. 1 shows an inertial micro-electro-mechanical system (MEMS) system 1 comprising an inertial MEMS device 2 and a control circuit 3, implemented as an Application Specific Integrated Circuit (ASIC), that includes circuitry for controlling operation of the inertial MEMS device 2.

The inertial MEMS system 1 is, for example, packaged in a housing 5 and further comprises a power supply circuit 6, for example a rechargeable battery, which may be enclosed in the housing 5 or be external.

The control circuit 3 receives signals sn, typically movement signals, from the inertial MEMS device 2 and sends electrical supply and control quantities (for example a voltage P) to the inertial MEMS device 2.

The inertial MEMS device 2 incorporates a wake-up element (reference 10 as shown in FIG. 2).

In detail, with reference to FIG. 2, the inertial MEMS device 2 here comprises a movable mass 9 and the wake-up element, indicated by reference 10 and overlying the movable mass 9.

The inertial MEMS device 2 is electrically coupled to the control circuit 3, for example through first conductive tracks 11A, first contact pads 12A and first wires 13A, in a per se known manner, for exchanging electrical quantities (power supply, movement signals sn).

The wake-up element 10, as discussed in detail below, is formed here by a suspended structure, such as a membrane or cantilever, carrying a piezoelectric structure.

The piezoelectric structure is electrically coupled to the control circuit 3, for example through one or more second conductive tracks 11B, one or more second contact pads 12B and one or more second wires 13B, and provides awakening signals, here awakening signal a1.

The wake-up element 10, being a piezoelectric structure arranged on a membrane or cantilever, does not require power supply and is capable of generating an output current if subject to shocks, accelerations or other movements; this current may be sensed and cause the activation of the inertial MEMS system 1.

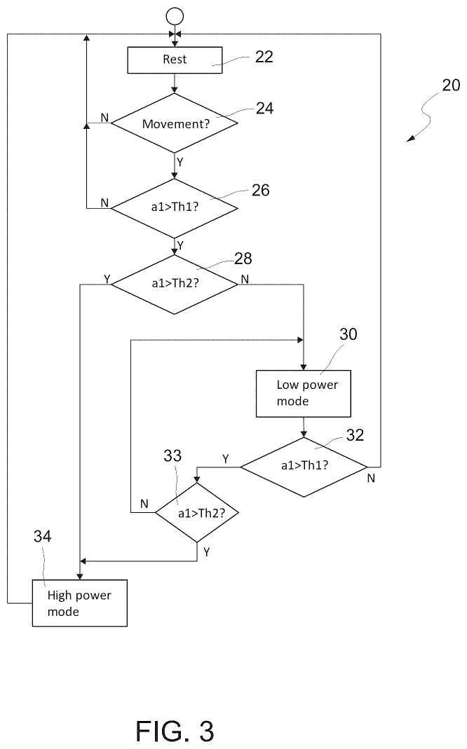

In particular, activation may occur according to two activation modes, depending on the extent of the environmental change sensed, as shown in the flow diagram 20 of FIG. 3.

In detail, in absence of environmental changes, the inertial MEMS system 1 is in rest condition, block 22. In this condition, the inertial MEMS device 2 is off, it receives no power supply and the control circuit 3 operates in a minimum activity condition, with very low consumption. For example, in this condition, the inertial MEMS system 1 may consume a current of a few nA (nanoAmpere)/sec.

When the wake-up element 10 senses a movement, an acceleration or shock, output Y from block 24, it generates an awakening signal a1. The awakening signal a1 (for example, a continuous signal) is provided by the wake-up element 10 to the control circuit 3 which verifies its amplitude.

If the awakening signal a1 is lower than a first threshold Th1, output N from block 24, the inertial MEMS system 1 remains in the rest condition, returning to block 22.

If the awakening signal a1 exceeds the first threshold Th1, output Y from block 24, the control circuit 3 awakes the inertial MEMS system 1, comprising the inertial MEMS device 2 and its own circuits intended for powering the inertial MEMS device 2 and for processing the signals sn provided by the latter.

In particular, if the awakening signal a1 is higher than the first threshold Th1, but lower than a second threshold Th2 (where the second threshold is higher than the first threshold Th1), output N from block 24, control circuit 3 activates the inertial MEMS device 2 in low-power (low-frequency and low-consumption) mode, block 30. For example, in this condition, inertial MEMS device 2 may work with a sampling frequency of a few Hz (for example, 1.6 Hz), providing the relevant measured signal samples at such frequency. In this case, for example, the inertial MEMS system 1 may have a total consumption of the order of a few hundreds of nA (nanoAmpere)/sec.

In this working condition, the accuracy of the movement information provided by the inertial MEMS system 1 is not high, but may be sufficient for some low-requirement applications (low-power working condition).

Furthermore, in this working condition, the control circuit 3 continues to monitor the awakening signal a1. If this signal a1 remains lower than the first threshold Th1, output N from block 32, after some time the control circuit 3 stops powering the inertial MEMS device 2 and returns to the rest condition of block 22.

Conversely, if the awakening signal a1 is higher than the first threshold Th1, output Y from block 32, it is verified whether the awakening signal a1 has become higher than the second threshold Th2, block 33. If not, output N from block 33, the inertial MEMS system 1 remains in the low-power mode, returning to block 30. If it becomes higher, output Y from block 33, the control circuit 3 causes the inertial MEMS system 1 to work in the high-power (high-frequency, high-consumption) working mode, block 34.

Similarly, returning to block 28, if the awakening signal a1 is higher than the second threshold Th2, output Y from block 28, the control circuit 3 activates the inertial MEMS device 2 so as to cause it to operate in high-power (high-frequency, high-consumption) mode, block 34.

For example, in the high-power mode, block 34, the inertial MEMS device 2 may work with a sampling frequency of more than 1500 Hz, providing the relative signal samples sn to the control circuit 3 at this frequency. In this case, for example, the inertial MEMS system 1 may have a total consumption of the order of a few tens of uA (microAmpere)/sec.

The inertial MEMS system 1 remains in the high-power working mode (block 34) as long as the awakening signal a1 provided by the wake-up element 10 remains higher than the second threshold Th2 and/or as long as the control circuit 3 receives the movement signals sn (movement signals sn greater than the movement threshold). In this case, the control circuit 3 stops powering the inertial MEMS device 2 and takes the inertial MEMS system 1 back to the rest condition, returning to block 22. Obviously, the control circuit 3 may provide for more complex logics and verifications for activating the high-power operating mode, to take into account particular functions and/or specific applications.

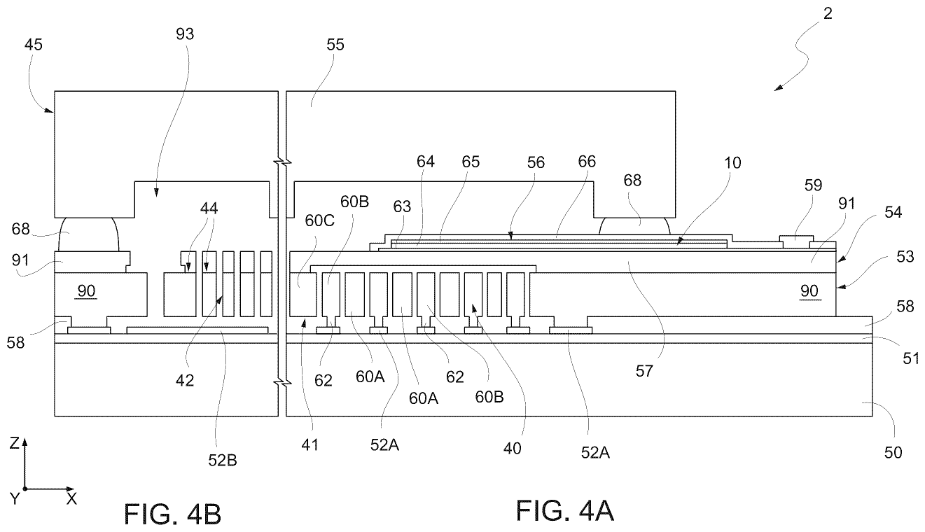

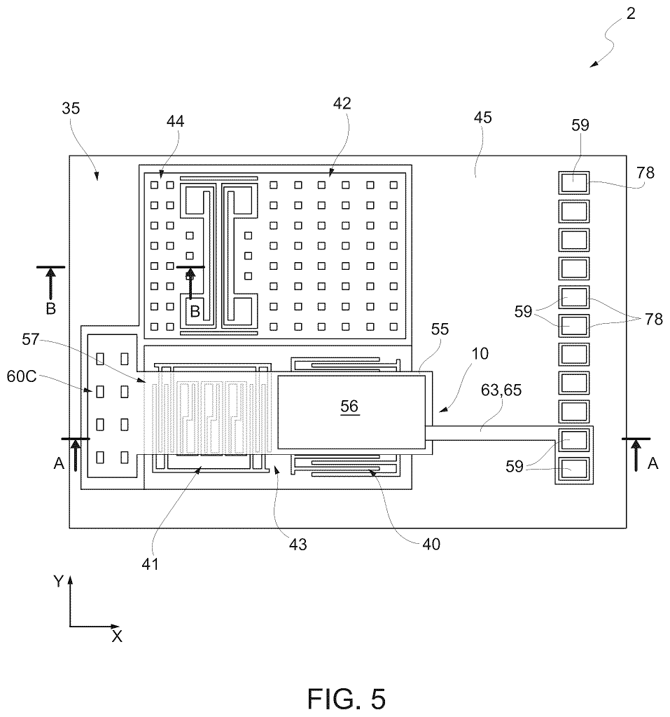

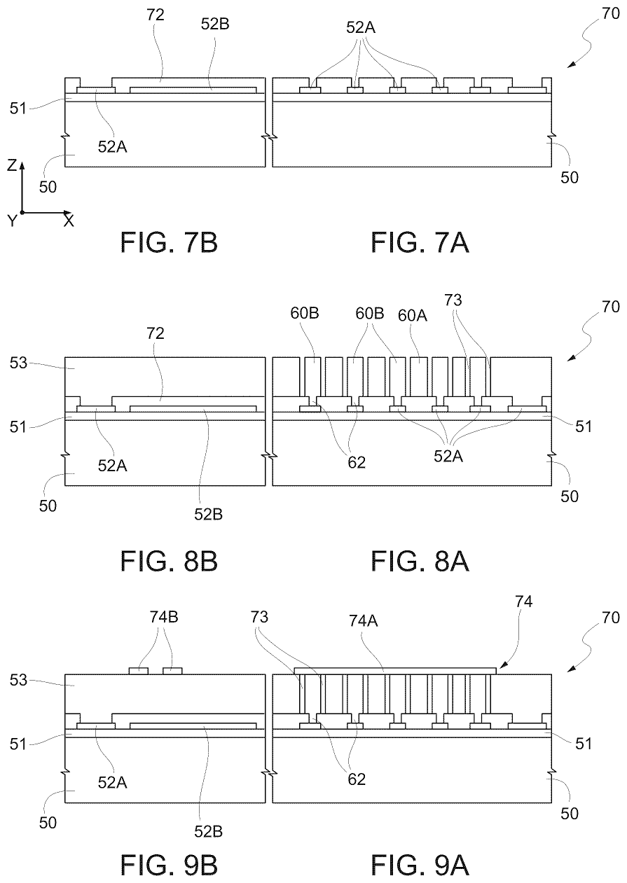

FIGS. 4A and 4B show a possible implementation of the inertial MEMS device 2 incorporating the wake-up element 10. It should be noted that, for a better understanding of the structure and the manufacturing process, FIGS. 4A and 4B (as well as the following FIGS. 7A-15A and 7B-15B) show side by side two distinct zones of the inertial MEMS device 2, as indicated by the arrows A-A and B-B of FIG. 5.

In particular, FIGS. 4A and 4B and FIG. 5 refer to an inertial MEMS device 2 comprising an inertial sensor, here a triaxial accelerometer 35, of a capacitive type.

The triaxial accelerometer 35 comprises a first sensing portion 40, a second sensing portion 41 and a third sensing portion 42. The sensing portions 40-42 include movable structures having a substantially planar extension, parallel to a plane XY of a Cartesian reference system XYZ.

In particular, in the embodiment of FIGS. 4A and 4B, the first sensing portion 40 is intended for sensing oscillations along a first horizontal axis X of the Cartesian reference system XYZ; the second sensing portion 41 is intended for sensing oscillations along a second horizontal axis Y of the Cartesian reference system XYZ; and the third sensing portion 42 is intended for sensing oscillations along a vertical axis Z of the Cartesian reference system XYZ.

In detail, the inertial MEMS device 2 of FIGS. 4A, 4B is formed in a die 45 of semiconductor material, comprising a substrate 50, for example made of monocrystalline silicon; an insulating layer 51, overlying the substrate 50, for example formed by a silicon oxide layer; conductive structures, for example made of polycrystalline silicon, overlying the insulating layer 51 and forming conductive regions 52A (for example the conductive tracks 11A, 11B of FIG. 2) and second fixed electrodes (here a lower electrode 52B of the third sensing portion 42 is visible); a first structural layer 53, for example made of polycrystalline silicon, overlying the insulating layer 51 and the conductive structures 52A and 52B (to which it may be electrically connected, as for the conductive regions 52A, or be coupled capacitively, as for the lower electrode 52B); a second structural layer 54, for example made of polycrystalline silicon, overlying the first structural layer 53 and mechanically and electrically coupled thereto in some zones; a piezoelectric stack 56, overlying the second structural layer 54; and a cap 55, for example made of monocrystalline silicon, overlying and attached to the second structural layer 54.

In the embodiment of FIGS. 4A, 4B, the first structural layer 53 has a greater thickness than the second structural layer 54. For example, the first structural layer 53 may have a thickness comprised between 2 and 80 μm and the second structural layer 54 may have a differentiated thickness according to the zones and comprised between 1 and 2 μm. In general, the second structural layer 54 may have a widely variable thickness, according to the application, comprised between 0.5-1 μm and 80 μm.

Furthermore, the inertial MEMS device 2 of FIGS. 4A, 4B comprises dielectric regions 58, arranged between the insulating layer 51 and the first structural layer 53; electrical connection regions 59, for example made of metal such as AlCu (aluminum-copper), arranged above the second structural layer 54 for forming electrical connections, for example made of the contact pads 12A, 12B of FIGS. 4A, 4B; and bonding regions 68, of adhesive material, such as glassfrit, arranged between the cap 55 and the second structural layer 54.

In particular, the first structural layer 53 and the second structural layer 54 are patterned and locally thinned so as to define movable and fixed structures of the triaxial accelerometer (movable masses, electrodes, suspension springs) and to electrically separate the various portions of the die 45.

The inertial MEMS device 2 has therefore structures having at least three thicknesses, and precisely structures having a first thickness, equal to the thickness of the first structural layer 53, structures having a second thickness, equal to the sum of the thicknesses of the first and the second structural layers 53, 54; and structures having a third thickness, lower than the thickness of the second structural layer 54, due to a partial removal of the thickness of the second structural layer 54, as explained in detail below.

For example, in the embodiment shown in FIGS. 4A, 4B, the first and the second sensing portions 40, 41 have first movable electrodes 60A and first fixed electrodes 60B formed by only the first structural layer 53 and therefore have the first thickness; the third sensing portion 42 has the second movable mass 44 (forming second movable electrodes) formed, in the portion shown, by both structural layers 53, 54 and therefore has the second thickness; and a cantilever 57 extends above the first and the second sensing portions 40, 41 and is formed by the second structural layer 54, locally thinned, and therefore has the third thickness.

In FIGS. 4A, 4B part of a suspended mass 60C is also visible, integral with one end of the cantilever 57, formed by the first and the second structural layers 53 and therefore having the first thickness. The suspended mass 60C is here arranged laterally to the second sensing portion 40, 41, as visible in FIG. 5.

The piezoelectric stack 56 extends on the cantilever 57 and forms, with the latter, the wake-up element 10 of FIG. 2. In a manner not shown, an insulating layer extends between the piezoelectric stack 56 and the cantilever 57, electrically insulating them.

The first fixed electrodes 60B are directly and electrically connected to respective conductive regions 52A through support and connection portions 62 and face respective first movable electrodes 60A.

In particular, the first movable electrodes 60A and the first fixed electrodes 60B face each other at facing surfaces extending in the thickness direction of the first structural layer 53 (perpendicularly to the extension plane XY of the movable structures of the sensing portions 40-42).

The second movable mass 44 overlies and is capacitively coupled to the lower electrodes 52B, in a direction perpendicular to the extension plane of the triaxial accelerometer 35.

The cantilever 57 is suspended on the first structural layer 53 and more precisely, in this embodiment, extends above the first and the second sensing portions 40, 41.

In particular, here, the cantilever 57 is supported at a first end (on the right in FIG. 4A) rigid with fixed portions of the die 45 and has a second end (on the left in FIG. 4A) integral with the suspended mass 60C. In this manner, the cantilever 57 has a high sensitivity.

The piezoelectric stack 56 comprises a lower electrode region 63, formed by a first conductive layer (single or multiple); a piezoelectric region 64, of piezoelectric material; and an upper electrode region 65, formed by a second conductive layer (single or multiple).

For example, the lower electrode region 63 may be formed by a platinum (Pt) layer overlying a titanium (Ti) layer, or may comprise molybdenum (Mo) and/or doped polycrystalline silicon; the piezoelectric region 64 may be formed by a piezoelectric material such as a PZT (based on lead and titanium zirconate, Pbₓ[Zr_{y}Ti_{1-y}]O₃), or may comprise an aluminum nitride (AlN) or scandium-doped aluminum nitride (AlScN) layer; and the upper electrode region 56 may be formed by a plurality of layers including indium tin oxide (ITO) and a tungsten-titanium (TiW) alloy or by a molybdenum (Mo) or aluminum-copper (AlCu) layer.

In particular, according to one embodiment, the piezoelectric stack 56 may comprise an aluminum nitride layer (lower layer) and a molybdenum layer (upper layer) for the lower electrode region 63 (in which case, an insulating layer below the piezoelectric stack 56 is not necessary); a crystalline aluminum nitride (AlN) layer for the piezoelectric region 64; and a molybdenum layer for the upper electrode region 65.

According to a variant, the piezoelectric region 64 may be formed by potassium sodium niobate (KNN), with lower and upper electrodes 63, 65 of platinum.

The layers forming the upper electrode region 64 may extend above the second structural layer 54, beyond the piezoelectric stack 56, to form the conductive track 11B of FIG. 2 and be in direct electrical contact with one of the electrical connection regions 59.

A protection dielectric layer 66, for example made of non-amorphous aluminum nitride (AlN), covers the piezoelectric stack 56 and is open at the electrical connection regions 59 for electrically connecting the lower electrode region 63 and the upper electrode region 65.

The cap 55 has (in top-view) a smaller area than the first and the second structural layers 53, 54 and is rigid with fixed portions formed by the first structural layer 53 (first fixed portions 90 rigid with to the substrate 50) and by the second structural layer 54 (second fixed portions 91 overlying and rigid with the first fixed portions 90).

The cap 55 is rigid with the second fixed portions 91 and forms, together with the substrate 50, the first and the second fixed portions 90, 91, a chamber 93 enclosing the inertial sensor (triaxial accelerometer) 35 and the wake-up element 10.

In this embodiment, the chamber 93 is closed; in this manner, the inertial sensor (triaxial accelerometer) 35 and the wake-up element 10 are contained in an environment closed to the outside and are protected from environmental damage, while being free to move for sensing movements of the inertial MEMS device 2. Furthermore, the wake-up element 10 is positioned in close proximity to the inertial sensor 35, thereabove, and therefore does not require additional space and has high sensitivity.

Furthermore, since the wake-up element 10 is positioned in close contact with the sensing portions 40-42, inside the chamber 93, it is not subject to damping due to the atmosphere.

A possible shape of the cantilever 57 is shown in FIG. 5.

Here, the first and the second sensing portions 40, 41 (for sensing oscillations along the first horizontal axis X and, respectively, oscillations along the second horizontal axis Y) are arranged side by side, along the first horizontal axis X, and comprise a first movable structure 43 integral with the movable electrodes 60A.

The third sensing portion 42 (for sensing oscillations along the vertical axis Z) is here arranged side by side with the first and the second sensing portions 40, 41 along the second horizontal axis Y, and has a second movable mass 44, forming second movable electrodes.

The cantilever 57 has here a rectangular shape and extends above the first and the second sensing portions 40, 41.

In particular, in FIG. 5, the cantilever 57 has a length (in the direction parallel to the first horizontal axis X) approximately equal to the sum of the lengths of the first and the second sensing portions 40, 41 along the same first horizontal axis X.

Furthermore, the cantilever 57 has a width (in the direction parallel to the second horizontal axis Y), lower than the size of the first sensing portion 40 (or of the second sensing portion 41) along the same second horizontal axis Y, even if this is not essential.

The piezoelectric stack 56 may extend only on the first sensing portion 40, as shown, or may extend along the entire cantilever 57.

As an alternative to what is shown, the wake-up element 10 might be arranged only on the first or the second sensing portion 40, 41; furthermore, the inertial MEMS device 2 might have two wake-up elements 10, one for each sensing axis X, Y, for greater sensitivity, or one for each sensing portion 40, 41. Furthermore, the wake-up element 10 might also, or only, be formed on the third sensing portion 42.

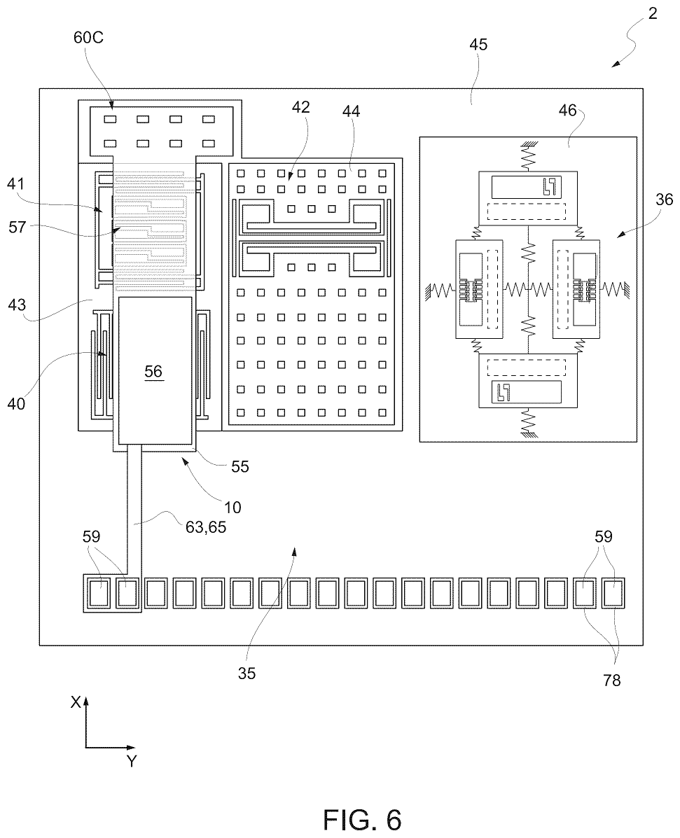

FIG. 6 shows a different implementation of the inertial MEMS device 2. Here, the inertial MEMS device 2 comprises, in addition to the inertial sensor (triaxial accelerometer) 35, another inertial sensor, here a gyroscope 36.

The gyroscope 36 is accommodated in the chamber 93 together with the triaxial accelerometer 35 and has a movable mass 46.

Also in this embodiment, the wake-up element 10 extends above the first and the second sensing portions 40, 41, between a fixed portion of the die 45 and the suspended mass 60C, but it might extend on only one of the sensing portions 40, 41.

Furthermore, if the or part of the third sensing portion 42 and/or of the gyroscope 36 are formed only in the first structural layer 53, the wake-up element 10 might (also or alternatively) be formed over one or both of them, so as to have more wake-up elements 10 on two or more sensing portions 40-42 and/or on the gyroscope 36.

The inertial MEMS device 2 is completely off in rest condition.

When the inertial MEMS device 2 undergoes a shock or is moved, the suspended cantilever 57 bends and/or is subject to vibrations, causing the piezoelectric stack 56 to deform. As a result, this generates a signal having a small current that is provided to the control circuit 3. As described above with reference to FIG. 3, when the current of this signal (i.e., its magnitude) exceeds a certain threshold, the control circuit 3 senses it and may turn on the inertial MEMS system 1 in low-power or high-power condition (depending on whether or not this current exceeds the first threshold Th1 or the second threshold Th2).

The inertial MEMS device 2 of FIGS. 4A, 4B may be formed using the method as shown in FIGS. 7-15 and described hereinbelow. In these Figures, the layers and non-defined structures, where useful for understanding, are indicated with the same reference numerals as in FIGS. 4A, 4B.

In detail, FIGS. 7A, 7B show a sensor wafer 70 of semiconductor material comprising the substrate 50.

The insulating layer 51, for example thermally grown or deposited, has been formed on the substrate 50.

The conductive structures 52A, 52B have been formed on the insulating layer 51, for example by depositing a polycrystalline silicon layer and subsequent photolithographic definition.

A first sacrificial layer 72, for example made of silicon oxide, has been deposited and patterned above the conductive structures 52A, 52B. The first sacrificial layer 72 has been selectively removed above the conductive structures 52A, for example where the support and connection portions 62 are to be grown as well as it is desired to grow any other anchoring and electrical and/or mechanical connection portions which connect the structures formed in the first structural layer 53 to the substrate 50.

Successively, FIGS. 8A, 8B, using an epitaxial growth process, the first structural layer 53 is grown on the sensor wafer 70. The first structural layer 53 then grows where the first sacrificial layer 72 has been selectively removed, forming the support and connection portions 62.

Still with reference to FIGS. 8A, 8B, the first structural layer 53 is etched, for example by dry etching, where it is desired to form the first and the second sensing portions 40, 41 and any parts of the third sensing portion 42 (where structures having the first thickness are intended to be formed). Thus, first trenches 73 are formed which extend completely through the first structural layer 53. The etching automatically stops on the first sacrificial layer 72 and leads to the definition of the first movable electrodes 60A and the first fixed electrodes 60B.

Then, FIGS. 9A, 9B, a second sacrificial layer 74, for example made of TetraEthylOrthoSilicate (TEOS), is deposited for a thickness comprised, for example, between 0.1 μm and 5 μm. The second sacrificial layer 74 may partially fill the first trenches 73, although such filling is not important.

The second sacrificial layer 74 is then planarized and selectively removed. Sacrificial portions are thus formed where it is desired that the second structural layer 54 be separated from the first structural layer 53 and/or have a reduced thickness. In particular, in this step a first sacrificial region 74A, where it is desired to form the cantilever 57 of FIGS. 4A, 4B, as explained below, as well as second sacrificial regions 74B are formed.

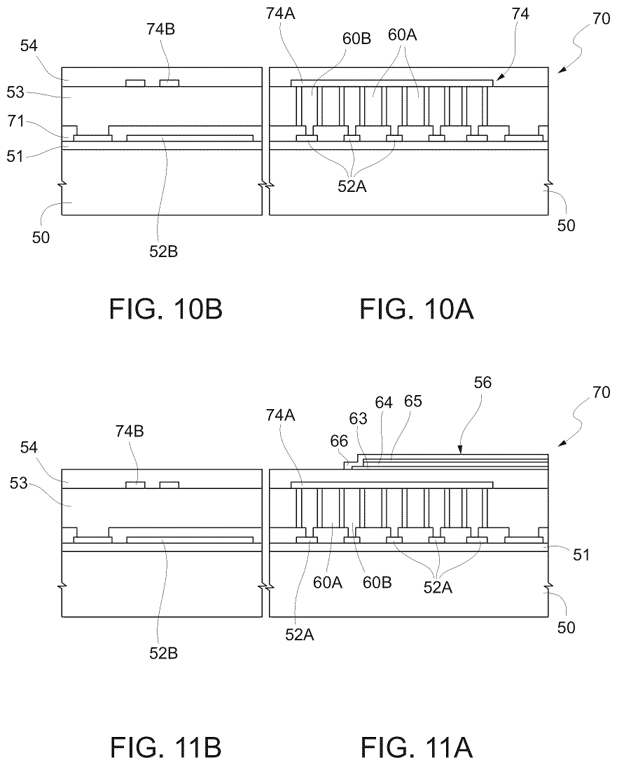

With reference to FIGS. 10A, 10B, the second structural layer 54 is grown above the first structural layer 53 and the second sacrificial layer 74. The second structural layer 54 is epitaxially grown and planarized, for example by Chemical Mechanical Polishing (CMP) so that, where no sacrificial regions 74A and 74B are present, a complete structural layer having the third thickness is formed. For example, in this embodiment, the third thickness may be comprised between 1 and 2 μm.

Subsequently, FIGS. 11A, 11B, the piezoelectric stack 56 is formed, by depositing and patterning suitable layers to form the lower electrode region 63, the piezoelectric region 64, and the upper electrode region 65. Furthermore, the protection dielectric layer 66 is deposited and opened where it is desired to contact the electrode regions 63, 65.

Then, in a manner not shown, the electrical connection regions 59, for example made of AlCu, are formed in electrical contact with the electrode regions 63, 65 (as regards the second contact pads 12B of FIG. 2) and with corresponding underlying portions of the first and the second structural layers 53, 54 (as regards the first contact pads 12A of FIG. 2).

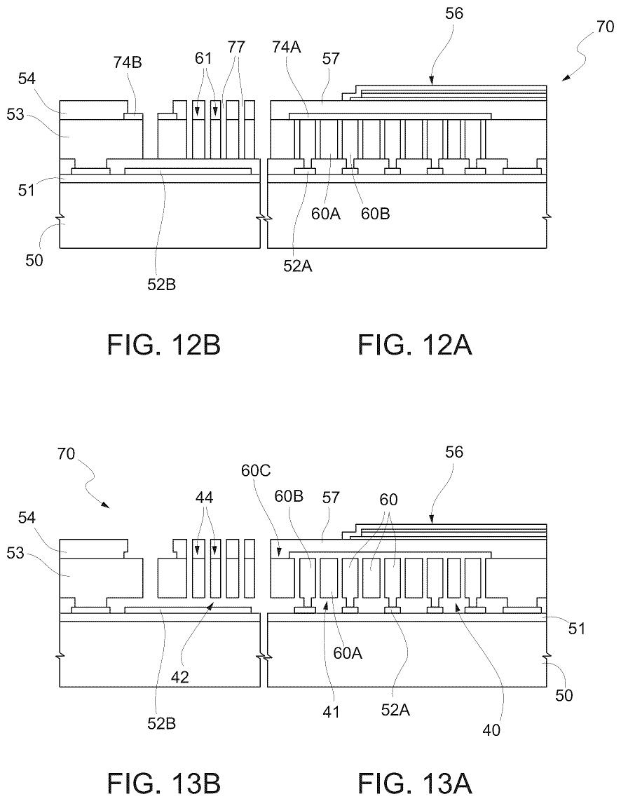

Subsequently, FIGS. 12A, 12B, the sensor wafer 70 is etched to define the structures formed by the sole second structural layer 54 or by both structural layers 53, 54, so as to separate them from the rest of the sensor wafer 70. In particular, here, using a mask not shown, the second structural layer 54 and the first structural layer 53 are dry etched.

In detail, in this step, the second movable mass 44 of the third sensitive zone 42 is defined and holes 77 are formed through the second movable mass 44. The second movable mass 44, in the part shown, therefore has the second thickness, equal to the sum of the thicknesses of the first and the second structural layers 53, 54.

Furthermore, in a manner not shown, the cantilever 57 as well as any other structures formed only in the second structural layer 54 are defined, where the first structural layer 53 is protected by the sacrificial regions 74A and 74B.

In this step, the trenches 78 (visible in FIG. 5) are formed and delimit the portions of the complete structural layer 53, 54 below the electrical connection regions 59 (forming the first contact pads 12A) and in direct electrical contact with the conductive structures 52A and 52B through the conductive regions 52A.

The etching automatically stops on the first sacrificial layer 72.

Then, FIGS. 13A, 13B, the first and the second sacrificial layers 72, 74 are removed, where exposed, for example in hydrofluoric acid (HF), freeing the first movable electrodes 60A and the second movable mass 44.

Furthermore, the first movable electrodes 60A are separated from the respective fixed electrodes 60B and the second movable mass 44 is separated from the lower electrode 52B.

In this step, in particular, the sacrificial region 74A is removed, above the first sensing portion 40, freeing the cantilever 57.

FIGS. 13A, 13B show the sensing portions 40-42 completely defined and free.

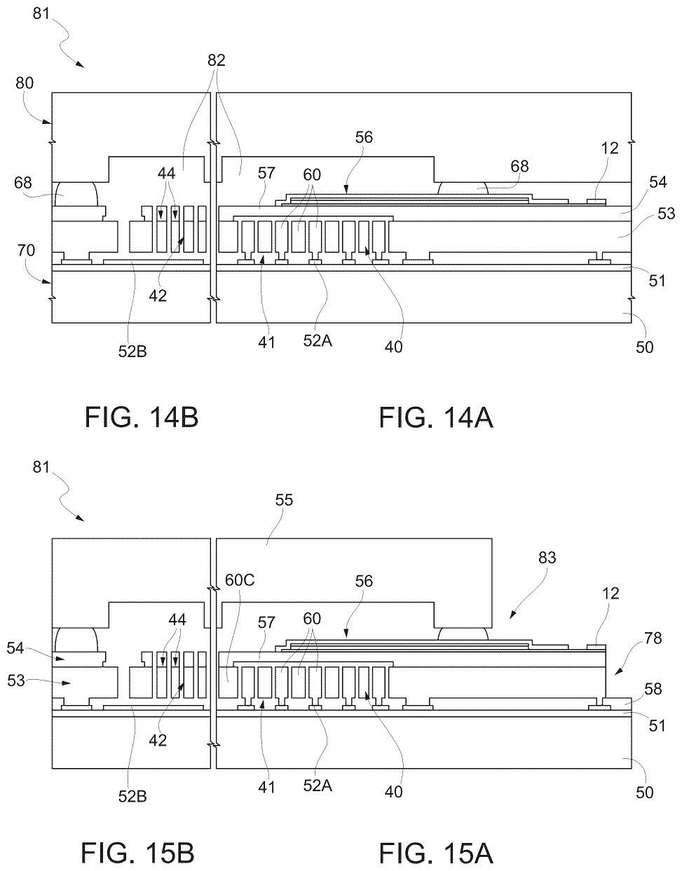

In FIGS. 14A, 14B a cap wafer 80 is attached to the sensor wafer 70 through the bonding regions 68, forming a composite wafer 81. It should be noted that FIGS. 14A, 14B show a wider area of the composite wafer 81 with respect to the sensor wafer 70 of FIGS. 7A-13, and specifically show the area of the contact pads 12 (on the right).

In these Figures, for the sake of simplicity, the first movable electrodes 60A and the first fixed electrodes 60B are generally indicated by 60.

The cap wafer 80 may have previously been worked to form recesses 82 above the sensing portions 40-42 and the wake-up element 10, allowing ample freedom of movement thereof.

The sensor wafer 70 may therefore be thinned, for example by CMP, so as to have a desired thickness in the direction of the vertical axis Z.

Then, FIGS. 15A, 15B, the cap wafer 80 is cut, for example by laser, to open a window 83 above the contact pads 12 (only one of the second contact pads 12B of FIG. 2 is visible in FIG. 15A,).

Then the overall wafer 81 is diced to form the inertial MEMS device 2 of FIGS. 4A, 4B and 5.

In this manner, the wake-up element 10 may be easily integrated into a manufacturing process of a MEMS inertial sensor, and therefore at a very low cost, by simply modifying the masks and forming the piezoelectric stack 56.

Furthermore, as discussed above, the wake-up element 10 requires no additional space compared to the inertial sensor(s) integrated in the inertial MEMS device 2 and this may be used even in circuits and apparatuses having very small dimensions.

In addition, the wake-up element 10 is protected from the external environment and has high sensitivity.

Finally, it is clear that modifications and variations may be made to the inertial MEMS device, the inertial MEMS system and the manufacturing process described and illustrated without thereby departing from the scope of the present invention, as defined in the attached claims.

For example, in the flow diagram of FIG. 3, the transition from low-power mode operation to high-power working mode (block 33) may be determined by different conditions.

An artificial intelligence algorithm may be trained to recognize the type (extent) of the movement of the inertial MEMS device and, upon sensing a fast movement (e.g., running), bring the inertial MEMS system 1 into the high-power working mode, block 34. Conversely, if the algorithm senses a movement, but not a fast movement, it may leave the inertial MEMS system 1 in the low-power mode, returning to block 30 and enter the rest condition of block 22 only in absence of movement for a certain period of time (e.g., between 5 and 30 seconds), depending on the application.

Furthermore, as indicated above, multiple cantilevers 57 may be present; the cantilevers may be arranged only on the first, the second or the third sensing portions 40, 41, 42. Multiple cantilevers may be provided on the same sensing portion 40-42 or on the gyroscope 36 and the cantilever may be of projecting type, attached and integral at only one end to fixed or movable parts; or may be supported at both ends.

1. An inertial MEMS device, comprising:
an inertial element responsive to movement, the inertial element including a movable structure formed in a first structural layer made of semiconductor material;
a suspended structure extending above the movable structure, at a distance therefrom, the suspended structure being formed in a second structural layer made of semiconductor material; and
a piezoelectric structure arranged on the suspended structure;
wherein the suspended structure and the piezoelectric structure form a wake-up element configured to generate an activation signal in response to vibrations or shocks.

2. The inertial MEMS device according to claim 1, wherein the suspended structure is one of a cantilever or a membrane.

3. The inertial MEMS device according to claim 1, further comprising:
a substrate made of semiconductor material;
wherein the first structural layer extends on the substrate and comprises first fixed portions rigid with the substrate;
wherein the second structural layer comprises second fixed portions in direct contact with the first fixed portions; and
a cap structure rigidly coupled to the second fixed portions to form a chamber enclosing the inertial element and the wake-up element.

4. The inertial MEMS device according to claim 1, wherein the first structural layer is made of silicon and the second structural layer is made of silicon.

5. The inertial MEMS device according to claim 1, wherein the piezoelectric structure comprises:
a piezoelectric stack overlying the suspended structure and made of: a first conductive material providing a first electrode region; a piezoelectric region overlying the first electrode region and made of piezoelectric material; and a second electrode region overlying the piezoelectric region and made of a second conductive material providing a second electrode region;
wherein at least one of the first electrode region and the second electrode region is coupled to an external connection region.

6. The inertial MEMS device according to claim 1:
wherein the first structural layer has a first thickness;
wherein the second structural layer has a second thickness smaller than the first thickness;
wherein the second structural layer further has a thinned zone having a third thickness less than the second thickness, the thinned zone forming the suspended structure and extending at a distance from the first structural layer.

7. The inertial MEMS device according to claim 1, wherein the inertial element comprises one or more of an accelerometer and a gyroscope.

8. The inertial MEMS device according to claim 1, wherein the inertial element is of capacitive type.

9. An inertial MEMS system, comprising:
an inertial MEMS device of claim 1; and
a control circuit that is electrically coupled to the inertial MEMS device;
wherein the control circuit is configured to:
receive the activation signal;
compare the activation signal with a first threshold and a second threshold, the second threshold being greater than the first threshold;
activate the inertial MEMS device from a rest condition where the inertial MEMS device is turned off to a low-consumption operation mode in response to the activation signal being greater than the first threshold and smaller than the second threshold; and
activate the inertial MEMS device to a high-consumption operation mode in response to the activation signal being greater than the second threshold.

10. The inertial MEMS system according to claim 9, wherein the control circuit is further configured to:
after activation to the low-consumption operation mode: receive electric measurement signals from the inertial element; verify, after an acquisition time, whether one or more of the activation signal and the electric measurement signals are representative of predetermined movements; and deactivate the inertial MEMS device to the rest condition when the one or more of the activation signal and the electric measurement signals are not representative of predetermined movements.

11. A method for activating an inertial MEMS device from a rest condition where the inertial MEMS device is turned off, comprising:
receiving an activation signal indicative of presence of vibrations or shocks, said activation signal generated by a wake-up element comprising a suspended piezoelectric structure extending above a movable structure of the inertial MEMS device;
comparing the activation signal with a first threshold and a second threshold, wherein the second threshold is greater than the first threshold;
activating the inertial MEMS device from the rest condition to a low-consumption operation mode in response to the activation signal being greater than the first threshold and smaller than the second threshold; and
activating the inertial MEMS device to a high-consumption operation mode in response to the activation signal being greater than the second threshold.

12. A process for manufacturing an inertial MEMS device, comprising:
forming a first structural layer made of semiconductor material on a substrate;
forming an inertial element, including a movable structure, in the first structural layer;
forming a second structural layer made of semiconductor material on the first structural layer;
forming a suspended structure in the second structural layer, the suspended structure extending above the movable structure, at a distance therefrom; and
forming a piezoelectric structure above the suspended structure;
wherein the suspended structure and the piezoelectric structure form a wake-up element configured to generate an activation signal in response to vibrations or shocks.

13. The process according to claim 12, further comprising:
before forming the second structural layer, forming a sacrificial region above the movable structure;
after forming the piezoelectric structure, defining the second structural layer; and
removing the sacrificial region.

14. The process according to claim 12, further comprising attaching a cap structure to the second structural layer to form a chamber enclosing the inertial element and the wake-up element.
